(19) United States
(12) Patent Application Publication
(10) Pub. No.: US 2025/0107022 A1
(43) Pub. Date: Mar. 27, 2025

(54) ELECTRONIC DEVICE INCLUDING RACK GEAR GUIDE STRUCTURE

(71) Applicant: SAMSUNG ELECTRONICS CO., LTD., Suwon-si (KR)

(72) Inventors: Jooyoung KANG, Suwon-si (KR); Bongsoo KIM, Suwon-si (KR); Sejin PARK, Suwon-si (KR); Wanju BYUN, Suwon-si (KR); Sujeong CHO, Suwon-si (KR); Hyunju HONG, Suwon-si (KR)

(21) Appl. No.: 18/907,611

(22) Filed: Oct. 7, 2024

Related U.S. Application Data
(63) Continuation of application No. PCT/KR2024/013717, filed on Sep. 10, 2024.

(30) Foreign Application Priority Data
Sep. 26, 2023 (KR) 10-2023-0129380
Oct. 27, 2023 (KR) 10-2023-0145212

(51) Int. Cl. H05K 5/02

(52) U.S. Cl. CPC H05K 5/0217

(57) ABSTRACT

An electronic device includes a first housing, a second housing slidably coupled to the first housing, and a drive part. The drive part provides a driving force for sliding the second housing and includes a pinion gear and a drive motor configured to rotate the pinion gear. The electronic device further includes a rack gear and a guide structure. The rack gear is gear-coupled to the pinion gear to reciprocate in a predetermined section in accordance with a rotation of the pinion gear. The guide structure includes an accommodation space configured to accommodate at least a part of the rack gear and to guide the moving rack gear.

### CROSS-REFERENCE TO RELATED APPLICATIONS

This application is a continuation application of International Application No. PCT/KR2024/013717 designating the United States, filed on Sep. 10, 2024, and claiming priority to Korean Patent Application No. 10-2023-0129380 filed on Sep. 26, 2023, in the Korean Intellectual Property Office, and to Korean Patent Application No. 10-2023-0145212 filed on Oct. 27, 2023, in the Korean Intellectual Property Office, the disclosures of all of which are incorporated by reference herein in their entireties.

### TECHNICAL FIELD

Embodiments of the present disclosure relate to an electronic device including a rack gear guide structure.

### BACKGROUND ART

Electronic devices are gradually becoming slimmer, and the design factors of electronic devices are being enhanced and developed so that the electronic devices have improved rigidity, and the electronic devices have distinct functional elements. Due to enhancements in fabrication process and technology, electronic devices may gradually have various shapes departing from a uniform rectangular shape. For example, an electronic device may have a deformable structure so that a user may conveniently carry the electronic device and use a large screen display. Electronic devices may also include a rollable electronic device (e.g., a slidable electronic device) in which a display area of a flexible display (e.g., a rollable display) may be changed by supporting housings that operate to slide relative to each other. The rollable electronic device may require a structure in which a drive part (e.g., a drive module) capable of automatically sliding the other housing relative to one housing is efficiently disposed.

The information described above may be provided as the related art for the purpose of enhancing the understanding of the present disclosure. No assertion or determination is made with respect to the applicability of any of the above-mentioned as the prior art related to the present disclosure.

### DISCLOSURE OF INVENTION

### Technical Problem

Electronic devices may include a rollable electronic device (e.g., a slidable electronic device) in which a display area of a flexible display (e.g., a rollable display, an expandable display, or a stretchable display) may be expanded and/or contracted depending on operating states. The rollable electronic device may include first and second housings that may be movably coupled to each other by being at least partially fitted with each other. For example, the first and second housings operate to slide relative to each other and support at least a part of the flexible display. In this manner, the flexible display is induced to have a first display area in a slide-in state, and is induced to have a second display area larger than the first display area in a slide-out state.

The rollable electronic device may include a drive part (e.g., a drive module) including a drive motor. The drive motor includes a pinion gear disposed in any one housing (e.g., the first or second housing) of the electronic device and is configured to automatically slide the second housing by a designated reciprocation distance relative to the first housing gripped by a user. The electronic device further includes a rack gear that is disposed in the other housing (e.g., the second housing or the first housing) and gear-coupled to the pinion gear. For example, when the drive motor including the pinion gear is disposed in the first or second housing, the rack gear, which has a length in a sliding direction and is gear-coupled to the pinion gear, may be disposed in the other housing.

However, the rack gear may have a length corresponding to a reciprocation movement distance (e.g., a slide stroke) of the rollable electronic device, and one end of the rack gear may be fixed to any one housing. The rack gear may have a support structure provided in the form of a cantilevered beam extending to an internal space of the other housing. The support structure is highly likely to be damaged in the event of an external impact such as a fall of the electronic device, and the rigidity of the support structure may be low.

In addition, the rollable electronic device may be configured such that the two housings are guided by guide rails disposed on two opposite surfaces between the two housings. In this case, the guide rail may include a plurality of bearing members. Because the bearing members support the two housings in a thickness direction of the electronic device (e.g., a direction perpendicular to the sliding direction), there may occur a problem in that the electronic device sways in planar directions (e.g., upward, downward, leftward, and rightward directions when the flexible display is viewed from above) during an operation.

### Solution to Problem

Various embodiments of the present disclosure may provide an electronic device including a rack gear guide structure with improved impact resistance.

Various embodiments may provide an electronic device including a rack gear guide structure having support structures in various directions, thereby assisting in improving the fluidity.

Various embodiments may provide an electronic device including a rack gear guide structure capable of assisting in reducing a driving resistance force of a drive motor by reducing a frictional force during a sliding operation by providing a guide structure with an improved rack gear.

However, the object to be achieved by the present disclosure is not limited to the above-mentioned objects but may be variously expanded without departing from the spirit and scope of the present disclosure.

According to various embodiments, an electronic device may include a first housing, a second housing slidably coupled to the first housing, a drive part providing a driving force for sliding the second housing and including a pinion gear, and a drive motor configured to rotate the pinion gear, a rack gear gear-coupled to the pinion gear and configured to reciprocate in a predetermined section in accordance with a rotation of the pinion gear, and a guide structure including an accommodation space configured to accommodate at least a part of the rack gear, and configured to guide the moving rack gear.

### Advantageous Effects of Invention

The electronic device according to the exemplary embodiments of the present disclosure may provide the guide structure configured to guide the rack gear in accordance with the sliding operation. The guide structure may assist in improving impact resistance against an external impact such as a fall and improving the operational stability by blocking foreign substances. In addition, the stable sliding operation may be induced by the additional support structure implemented by the guide structure, and the driving resistance force of the drive motor may be reduced by reducing a frictional force by using the bearing member.

In addition, various effects that can be directly or indirectly identified through the present document may be provided.

The effects obtained by the present disclosure are not limited to the aforementioned effects, and other effects, which are not mentioned above, will be clearly understood by those skilled in the art from the following description.

### BRIEF DESCRIPTION OF DRAWINGS

In connection with the description of the drawings, the same or similar reference numerals may be used for the same or similar components.

FIG. 1 is a block diagram of an electronic device in a network environment according to various embodiments of the present disclosure.

FIGS. 2A and 2B are views illustrating front and rear surfaces of the electronic device in a slide-in state according to various embodiments of the present disclosure.

FIGS. 3A and 3B are views illustrating the front and rear surfaces of the electronic device in a slide-out state according to various embodiments of the present disclosure.

FIG. 4A is an exploded perspective view of the electronic device according to various embodiments of the present disclosure.

FIG. 4B is a perspective view of a support bracket on which a battery according to various embodiments of the present disclosure is seated.

FIG. 5A is a cross-sectional view of the electronic device according to various embodiments of the present disclosure when viewed along line 5a-5a in FIG. 2A.

FIG. 5B is a cross-sectional view of the electronic device according to various embodiments of the present disclosure when viewed along line 5b-5b in FIG. 3A.

FIG. 6A is a view illustrating arrangement positions of a rack gear and a guide structure in the slide-in state according to various embodiments of the present disclosure.

FIG. 6B is a view illustrating arrangement positions of the rack gear and the guide structure in the slide-out state according to various embodiments of the present disclosure.

FIG. 6C is a perspective view of the guide structure according to various embodiments of the present disclosure.

FIG. 7A is a configuration view illustrating the rear surface of the electronic device in the slide-in state according to various embodiments of the present disclosure.

FIG. 7B is a perspective view illustrating a rear surface of a second housing in the slide-in state according to various embodiments of the present disclosure.

FIG. 7C is a cut-away perspective view of the second housing according to various embodiments of the present disclosure when viewed along line 7c-7c in FIG. 7B.

FIG. 7D is a partially cut-away perspective view of the second housing according to various embodiments of the present disclosure when viewed along line 7d-7d in FIG. 7B.

FIG. 8 is a configuration view illustrating the rear surface of the electronic device in the slide-out state according to various embodiments of the present disclosure.

FIG. 9 is a cross-sectional view of the electronic device according to various embodiments of the present disclosure when viewed along line 9-9 in FIG. 7A.

FIG. 10 is a partial perspective view of the rack gear according to various embodiments of the present disclosure.

FIG. 11A is a perspective view of the guide structure according to various embodiments of the present disclosure.

FIG. 11B is a view illustrating a state in which the guide structure in FIG. 11A according to various embodiments of the present disclosure is applied to the electronic device.

FIGS. 12A and 12B are partial perspective views of the guide structure according to various embodiments of the present disclosure.

### MODE FOR THE INVENTION

Hereinafter, embodiments of the disclosure will be described in detail with reference to the accompanying drawings so that those ordinarily skilled in the art to which the disclosure pertains can easily practice them. However, the disclosure may be implemented in many different forms without being limited to those embodiments described herein. In relation to the description of the drawings, identical or similar reference symbols may be used for the same or similar components. Additionally, in the drawings and related descriptions, descriptions of well-known functions and configurations may be omitted for clarity and brevity.

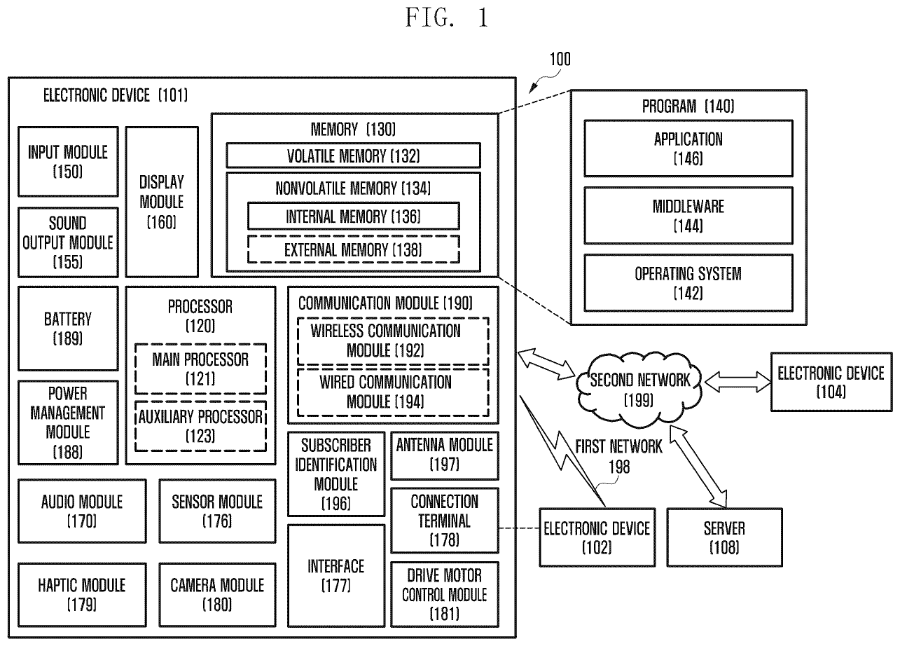

FIG. 1 is a block diagram illustrating an electronic device 101 in a network environment 100 according to various embodiments.

With reference to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. The non-volatile memory 134 may include internal memory 136 and/or external memory 138.

The program 140 may be stored in the memory 130 as software, and may include, For example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, For example, a microphone, a mouse, a keyboard, a key (e.g., a button), or a digital pen (e.g., a stylus pen).

The sound output module 155 may output sound signals to the outside of the electronic device 101. The sound output module 155 may include, For example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, For example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, For example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, For example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, For example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, For example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, For example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a lateral) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI).

According to an embodiment, commands or data may be transmitted or received between the electronic device 101 and the external electronic device 104 via the server 108 coupled with the second network 199. Each of the electronic device 102 or 104 may be a device of a same type as, or a different type, from the electronic device 101. According to an embodiment, all or some of operations to be executed at the electronic device 101 may be executed at one or more of the external electronic device 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The electronic device 101 may provide the outcome, with or without further processing of the outcome, as at least part of a reply to the request. To that end, a cloud computing, distributed computing, mobile edge computing (MEC), or client-server computing technology may be used, For example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) on the basis of 5G communication technology or IoT-related technology.

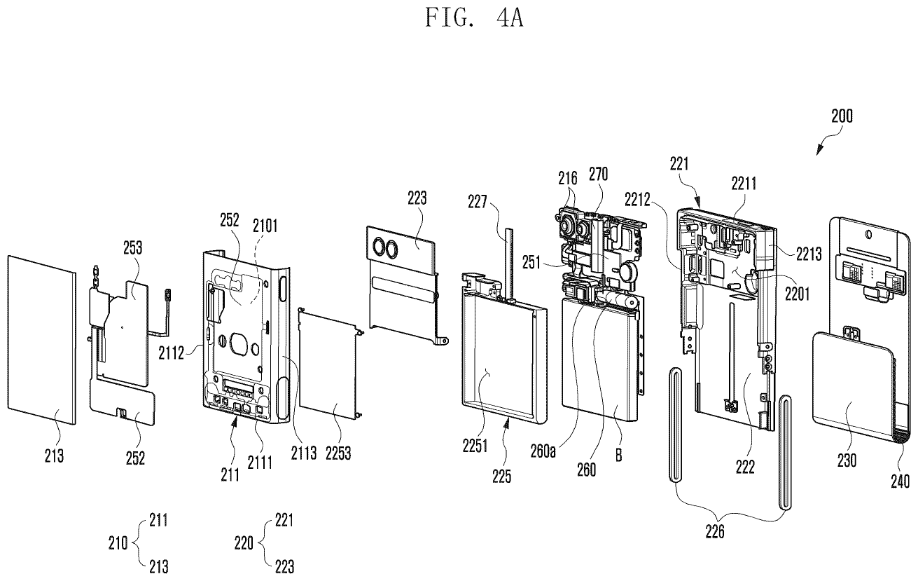

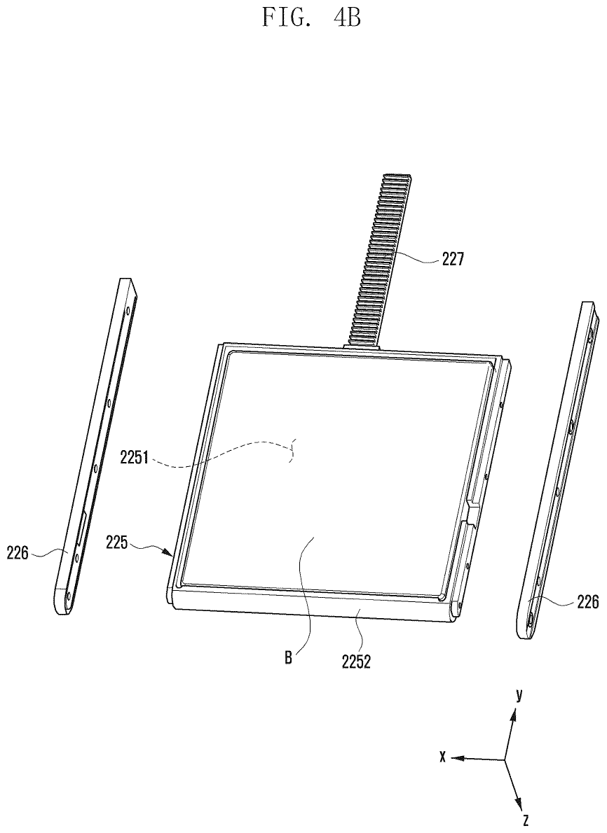

According to various embodiments, the sensor module 176 may include a movement distance detection sensor to detect a movement distance of a second housing (e.g., a second housing 220 in FIG. 4a) from a first housing (e.g., a first housing 210 in FIG. 4a) of an electronic device (e.g., an electronic device 200 of FIG. 4a). In one embodiment, through movement of the second housing 220 from the first housing 210, the sensor module 176 may detect a slide-in state being a first state, a slide-out state being a second state, or an intermediate state being a third state between the slide-in state and the slide-out state. In a certain embodiment, the processor 120 may detect the movement distance in real time through the sensor module 176 while the second housing 220 is moved from the first housing 210, and control the display module 160 to display an object in correspondence to the changing display area through a flexible display (e.g., flexible display 230 in FIG. 4a). In one embodiment, the electronic device 101 may include a drive motor control module 181 to control the operation of a drive motor (e.g., DC motor or stepping motor) (e.g., drive motor 260 in FIG. 4a) disposed inside the electronic device. In an embodiment, the drive motor control module 181 may be replaced by the processor 120.

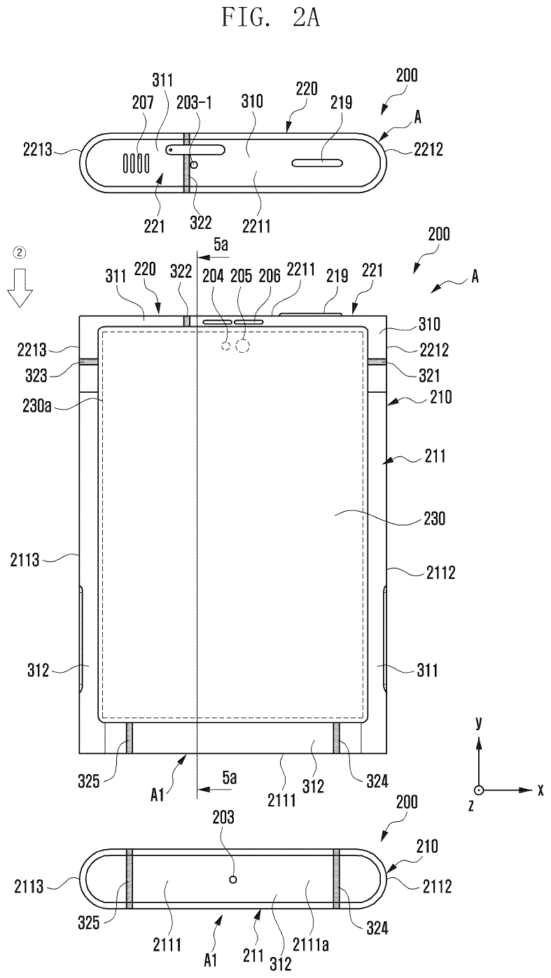

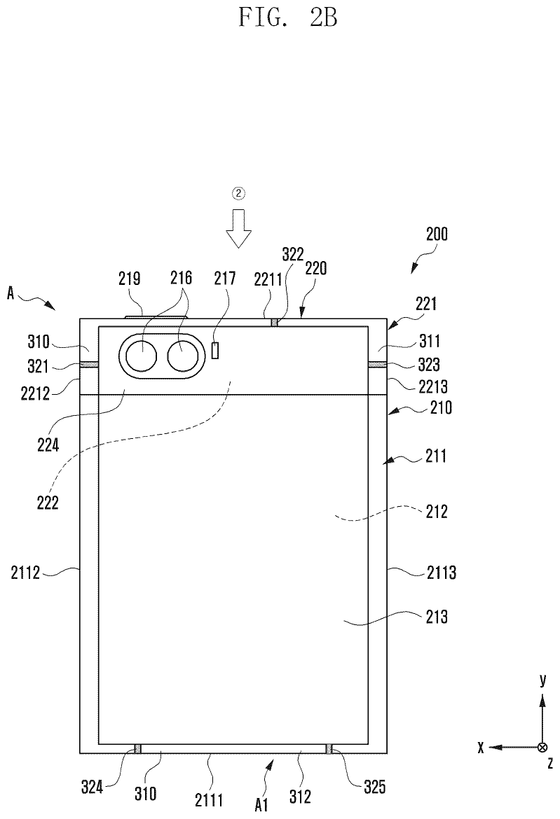

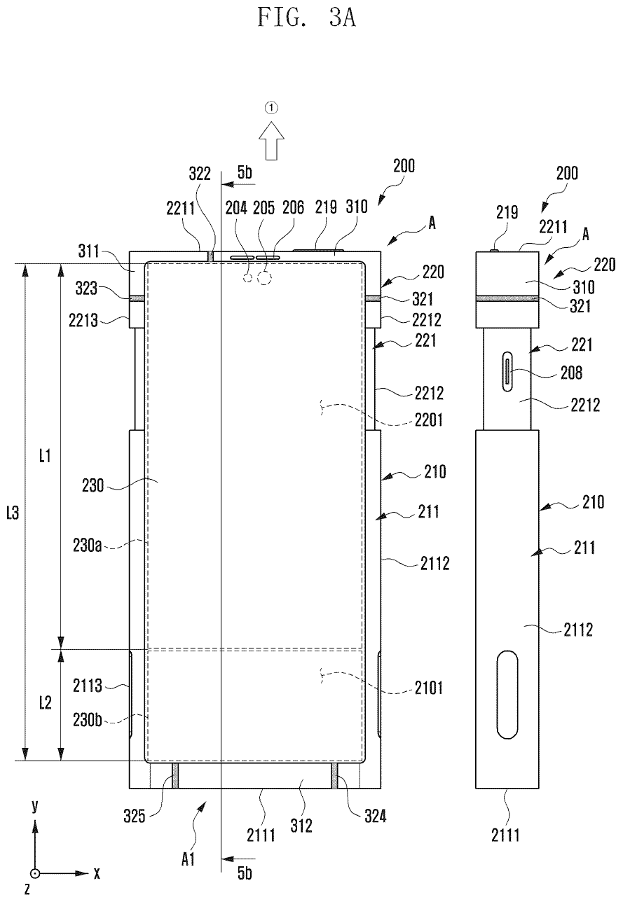

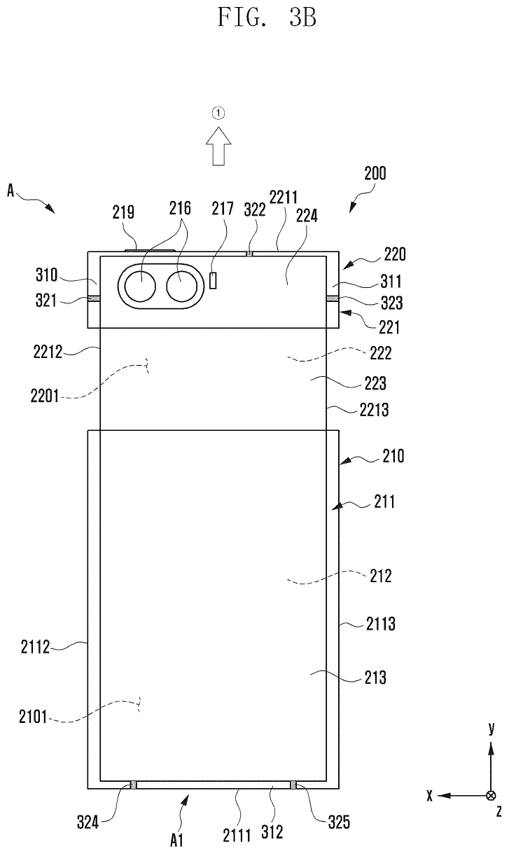

FIGS. 2A and 2B are views illustrating front and rear surfaces of the electronic device in a slide-in state according to various embodiments of the present disclosure. FIGS. 3A and 3B are views illustrating the front and rear surfaces of the electronic device in a slide-out state according to various embodiments of the present disclosure.

An electronic device 200 in FIGS. 2A to 3B may be at least partially similar to the electronic device 101 in FIG. 1 or further include other embodiments of the electronic device.

With reference to FIGS. 2A to 3B, the electronic device 200 may include a first housing 210 (e.g., a book cover or a first housing structure), a second housing 220 (e.g., a front cover or a second housing structure) slidably coupled to the first housing 210 in a designated direction (e.g., direction \textcircled{1} or direction \textcircled{2}) (e.g., a ± y-axis direction), and a flexible display 230 (e.g., a rollable display, an expandable display, or a stretchable display) disposed to be supported by at least one of the first housing 210 and the second housing 220. In the embodiment, the second housing 220 may be slidably coupled to the first housing 210 so that the second housing 220 slides outward (slide-out) in a first direction (direction \textcircled{1}) or slides inward (slide-in) in a second direction (direction \textcircled{2}) opposite to the first direction (direction \textcircled{1}) based on the first housing 210. In the embodiment, the electronic device 200 may switch to a first state, i.e., a slide-in state as at least a part of the second housing 220 is accommodated in at least a part of a first space 2101 defined by the first housing 210. In the embodiment, the electronic device 200 may switch to a second state, i.e., a slide-out state as at least a part of the second housing 220 moves in an outward direction (e.g., direction \textcircled{1}) from the first space 2101. In the embodiment, the electronic device 200 may include a support member (e.g., a support member 240 in FIG. 4A) (e.g., a bendable member, an articulated hinge module, a multi-bar assembly, or a multi-bar) that at least partially defines the same plane as at least a part of the second housing 220 in the slide-out state and is at least partially accommodated in the first space 2101 of the first housing 210 by being bent in the slide-in state. In the embodiment, at least a part of the flexible display 230 may be disposed to be supported by at least a part of the second housing 220. In the embodiment, at least a part of the remaining portion of the flexible display 230 may be disposed to be supported by the support member 240 (e.g., the support member 240 in FIG. 4A). In the embodiment, the support member (e.g., the support member 240 in FIG. 4A) may be disposed to be attached to a rear surface of the flexible display 230. In the embodiment, at least a part of the flexible display 230 is accommodated by being bent in the first space 2101 of the first housing 210 while being supported by the support member (e.g., the support member 240 in FIG. 4A) in the slide-in state, such that at least a part of the flexible display 230 may be disposed to be invisible or hidden from the outside. In the embodiment, at least a part of the flexible display 230 may be moved so as to be visible from the outside while being supported by the support member (e.g., the support member 240 in FIG. 4A) that at least partially defines the same plane as the second housing 220 in the slide-out state.

According to various embodiments, the first housing 210 may include a first lateral member 211, and the second housing 220 may include a second lateral member 221. In the embodiment, the first lateral member 211 may include a first side surface 2111 disposed at a lower side of the electronic device 200 and having a first length, a second side surface 2112 extending from one end of the first side surface 2111 in a vertical direction (e.g., the y-axis direction) and having a second length, and a third side surface 2113 extending from the other end of the first side surface 2111 in parallel with the second side surface 2112 and having the second length. In the embodiment, the first lateral member 211 may be at least partially configured as a conductive member (e.g., metal). In any embodiment, the first lateral member 211 may be formed by coupling a conductive member and a non-conductive member (e.g., polymer). In the embodiment, the first housing 210 may include a first extension member 212 extending from at least a part of the first lateral member 211 to at least a part of the first space 2101. In the embodiment, the first extension member 212 may be integrated with the first lateral member 211. In any embodiment, the first extension member 212 may be formed separately from the first lateral member 211 and structurally coupled to the first lateral member 211.

According to various embodiments, the second lateral member 221 may include a fourth side surface 2211 disposed at an upper side of the electronic device 200 and having a third length, a fifth side surface 2212 extending from one end of the fourth side surface 2211 in the vertical direction (e.g., the − y-axis direction) while corresponding to the second side surface 2112 and having a fourth length, and a sixth side surface 2213 extending from the other end of the fourth side surface 2211 in a direction parallel to the fifth side surface 2212 while corresponding to the third side surface 2113 and having the fourth length. In the embodiment, the second lateral member 221 may be at least partially configured as a conductive member (e.g., metal). In any embodiment, the second lateral member 221 may be formed by coupling a conductive member and a non-conductive member (e.g., polymer). In the embodiment, at least a part of the second lateral member 221 may include a second extension member 222 extending to at least a part of a second space 2201 of the second housing 220. In the embodiment, the second extension member 222 may be integrated with the second lateral member 221. In any embodiment, the second extension member 222 may be formed separately from the second lateral member 221 and structurally coupled to the second lateral member 221.

According to various embodiments, the second side surface 2112 and the fifth side surface 2212 may be slidably coupled to each other. In the embodiment, the third side surface 2113 and the sixth side surface 2213 may be slidably coupled to each other. In the embodiment, in the slide-in state, a part of the fifth side surface 2212 overlaps the second side surface 2112, such that a part of the fifth side surface 2212 may be disposed to be substantially invisible or hidden from the outside. In the embodiment, in the slide-in state, the remaining part of the fifth side surface 2212 may be disposed to be visible from the outside. In any embodiment, in the slide-in state, the fifth side surface 2212 may overlap the second side surface 2112, such that the fifth side surface 2212 may be disposed to be substantially invisible or substantially hidden from the outside. In the embodiment, in the slide-in state, a part of the sixth side surface 2213 may overlap the third side surface 2113, such that a part of the sixth side surface 2213 may be disposed to be substantially invisible or substantially hidden from the outside. In the embodiment, in the slide-in state, the remaining part of the sixth side surface 2213 may be disposed to be visible from the outside. In any embodiment, in the slide-in state, the sixth side surface 2213 may overlap the third side surface 2113, such that the sixth side surface 2213 may be disposed to be substantially invisible or hidden from the outside. In the embodiment, a part of the second extension member 222 may be disposed to be visible from the outside in the slide-in state. In any embodiment, in the slide-in state, the second extension member 222 may overlap the first extension member 212, such that the second extension member 222 may be disposed to be substantially invisible or hidden from the outside.

According to various embodiments, the first housing 210 may include a first rear surface cover 213 coupled to at least a part of the first lateral member 211. In the embodiment, the first rear surface cover 213 may be disposed by being coupled to at least a part of the first extension member 212. In any embodiment, the first rear surface cover 213 may be integrated with the first lateral member 211. In the embodiment, the first rear surface cover 213 may be made of polymer, coated or colored glass, ceramic, metal (e.g., aluminum, stainless steel (STS), or magnesium), or a combination of at least two of these materials. In any embodiment, the first rear surface cover 213 may extend to at least a part of the first lateral member 211. In any embodiment, the first rear surface cover 213 may be excluded, and at least a part of the first extension member 212 may be substituted with the first rear surface cover 213.

According to various embodiments, the second housing 220 may include a second rear surface cover 223 coupled to at least a part of the second lateral member 221. In the embodiment, the second rear surface cover 223 may be disposed by being coupled to at least a part of the second extension member 222. In the embodiment, the second rear surface cover 223 may be integrated with the second lateral member 221. In the embodiment, the second rear surface cover 223 may be made of polymer, coated or colored glass, ceramic, metal (e.g., aluminum, stainless steel (STS), or magnesium), or a combination of at least two of these materials. In any embodiment, the second rear surface cover 223 may extend to at least a part of the second lateral member 221. In any embodiment, the second rear surface cover 223 may be excluded, and at least a part of the second extension member 222 may be substituted with the second rear surface cover 223. In any embodiment, the second extension member 222 may be excluded, and the second rear surface cover 223 may be substituted with the second extension member 222. In the embodiment, the second housing 220 may include a window cover 224 disposed on at least a part of the second rear surface cover. In the embodiment, the window cover 224 may be disposed in an area exposed to the outside of the second housing 220 in the slide-in state. The window cover 224 may be made of a material that may allow at least one camera module 216 and/or at least one sensor module 217 disposed in an internal space 2201 of the second housing 220 to easily detect an external environment. For example, an area of the window cover 224, which at least corresponds to the camera module 216 and/or the sensor module 217, may be made of a transparent glass and/or polymer material. In any embodiment, the electronic device 200 may further include a cover member 2111a disposed to cover at least a part of the first side surface 2111 of the first housing 210.

According to various embodiments, the flexible display 230 may include a first part 230a (e.g., a planar portion) configured to be always visible from the outside, and a second part 230b (e.g., a bendable portion or a bending portion) extending from the first part 230a and accommodated by being at least partially bent in the first space 2101 of the first housing 210 in the slide-in state so that the second part 230b is invisible or hidden from the outside. In the embodiment, at least a part of the first part 230a may be disposed to be supported by the second housing 220, and the remaining part of the first part 230a and the second part 230b may be disposed to be at least partially supported by the support member (e.g., the support member 240 in FIG. 4A). In the embodiment, in the state in which the second housing 220 is slid outward in the first direction (direction \textcircled{1}), the second part 230b of the flexible display 230 may define substantially the same plane as the first part 230a while being supported by the support member (e.g., the support member 240 in FIG. 4A) and be disposed to be visible from the outside. In the embodiment, in the state in which the second housing 220 is slid inward in the second direction (direction \textcircled{2}), the second part 230b of the flexible display 230 may be accommodated by being bent in the first space 2101 of the first housing 210 and disposed to be invisible or hidden from the outside. Therefore, the display area of the flexible display 230 may vary as the second housing 220 slides in a designated direction (e.g., the ± y-axis direction) from the first housing 210.

According to various embodiments, a length of the flexible display 230 in the sliding direction (e.g., direction \textcircled{1} or direction \textcircled{2}) may vary as the second housing 220 slides relative to the first housing 210. For example, in the slide-in state, the flexible display 230 may have a first display area (e.g., an area corresponding to the first part 230a) corresponding to a first length L1. In the embodiment, in the slide-out state, the flexible display 230 may be expanded to have a second display area (e.g., an area including the first part 230a and the second part 230b) larger than the first display area and corresponding to a third length L3 longer than the first length L1 in accordance with a movement distance of the second housing 220 that has moved by a second length L2 relative to the first housing 210.

According to various embodiments, the electronic device 200 may include at least one of an input device (e.g., microphone 203-1) disposed in the second space 2201 of the second housing 220, a sound output device (e.g., a telephone receiver 206 and/or a speaker 207), sensor modules 204 and 217, camera modules (e.g., a first camera module 205 or a second camera module 216), a connector port 208, a key input device 219, and an indicator (not illustrated). In the embodiment, the electronic device 200 may include another input device (e.g., a microphone 203) disposed on the first housing 210. In any embodiment, the electronic device 200 may be configured to exclude at least one of the above-mentioned constituent elements or further include other constituent elements. In any embodiment, at least one of the above-mentioned constituent elements may be disposed in the first space 2101 of the first housing 210.

According to various embodiments, the input device may include the microphone 203-1. In any embodiment, the input device (e.g., the microphone 203-1) may include a plurality of microphones disposed to detect a direction of sound. For example, the sound output device may include the telephone receiver 206 and the speaker 207. In the embodiment, regardless of the slide-in state/slide-out state, the speaker 207 may correspond to the outside through at least one speaker hole formed in the second housing 220 at a position (e.g., on the fourth side surface 2211) always exposed to the outside. In the embodiment, in the slide-out state, the connector port 208 may correspond to the outside through a connector port hole formed in the second housing 220. In the embodiment, the connector port 208 may be covered to be invisible from the outside in the slide-in state. In any embodiment, in the slide-in state, the connector port 208 may correspond to the outside through an opening formed in the first housing 210 and corresponding to the connector port hole. In any embodiment, the telephone receiver 206 may include a speaker (e.g., a piezoelectric speaker) operating without a separate speaker hole.

According to various embodiments, the sensor modules 204 and 217 may generate electrical signals or data values corresponding to an internal operating state of the electronic device 200 or the external environment state. In the embodiment, for example, the sensor module 204 and 217 may include a first sensor module 204 (e.g., a proximity sensor or an illuminance sensor) disposed on the front surface of the electronic device 200, and/or a second sensor module 217 (e.g., a heart rate monitoring (HRM) sensor) disposed on the rear surface of the electronic device 200. In the embodiment, the first sensor module 204 may be disposed on the front surface of the electronic device 200 and provided below the flexible display 230. In the embodiment, the first sensor module 204 and/or the second sensor module 217 may include at least one of a proximity sensor, an illuminance sensor, a TOF (time of flight) sensor, an ultrasonic sensor, a fingerprint recognition sensor, a gesture sensor, a gyro sensor, an atmospheric pressure sensor, a magnetic sensor, an acceleration sensor, a grip sensor, a color sensor, an infrared (IR) sensor, a biosensor, a temperature sensor, and a humidity sensor.

According to various embodiments, the camera modules may include a first camera module 205 disposed on the front surface of the electronic device 200, and a second camera module 216 disposed on the rear surface of the electronic device 200. In the embodiment, the electronic device 200 may also include a flash (not illustrated) positioned in the vicinity of the second camera module 216. In the embodiment, the camera modules 205 and 216 may include one or a plurality of lenses, an image sensor, and/or an image signal processor. In the embodiment, the first camera module 205 may be disposed below the flexible display 230 and constituted to capture an image of a subject through a part of an activation area (e.g., the display area) of the flexible display 230.

According to various embodiments, the first camera module 205 among the camera modules and the first sensor modules 204 among the sensor module 204 and 217 may be disposed to detect the external environment through the flexible display 230. For example, the first camera module 205 or the first sensor modules 204 may be disposed in the second space 2201 of the second housing 220 and constituted to adjoin the external environment through a transmissive area formed in the flexible display 230 or an opening formed through the flexible display 230. In the embodiment, an area of the flexible display 230, which faces the first camera module 205, is a part of the activation area for displaying content and may define a transmissive area having a designated transmittance rate. In the embodiment, the transmissive area may be formed to have a transmittance rate within a range of about 5% to about 20%. The transmissive area may include an area that overlaps an effective area (e.g., a view angle area) of the first camera module 205 through which light, which enters an image sensor to create an image, passes. For example, the transmissive area of the flexible display 230 may include an area having a lower pixel arrangement density and/or wiring density than the periphery thereof. For example, the transmissive area may be substituted with the above-mentioned opening. For example, some of the camera modules 205 may include an under display camera (UDC). In any embodiment, some of the sensor modules 204 may be disposed in the second space 2201 of the second housing 220 and perform the function thereof without being visually exposed through the flexible display 230.

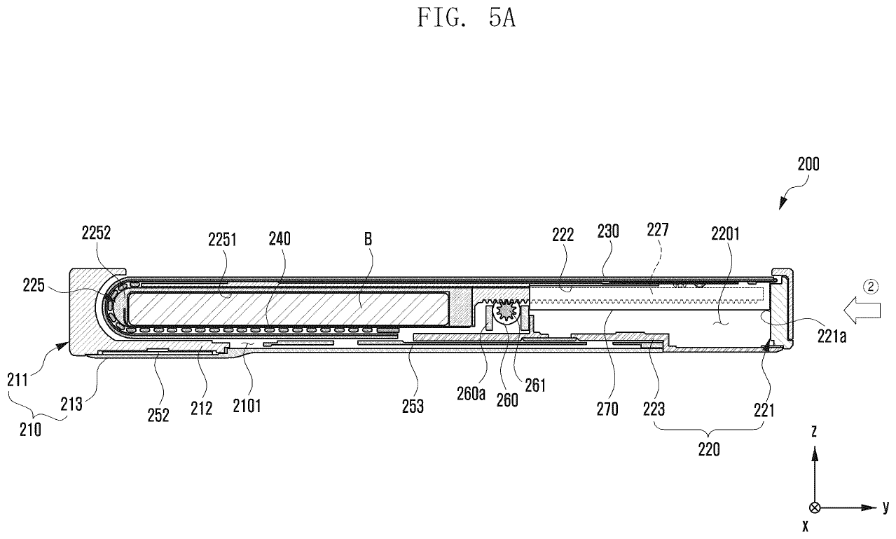

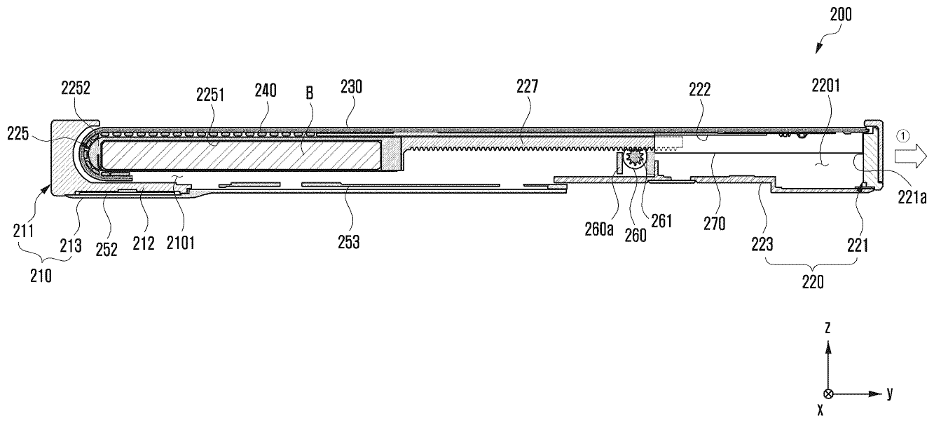

According to various embodiments, a slide-in operation and/or a slide-out operation of the electronic device 200 may be automatically performed. For example, the slide-in operation and/or the slide-out operation of the electronic device 200 may be performed by gear-coupling between a drive motor (e.g., a drive motor 260 in FIG. 4A) including a pinion gear (e.g., a pinion gear 261 in FIG. 5A) disposed in the second space 2201 of the second housing 220 and a rack gear (e.g., a rack gear 227 in FIG. 5A) disposed in the first space 2101 of the first housing 210, extending to at least a part of the second space 2201, and coupled to the pinion gear (e.g., the pinion gear 261 in FIG. 5A). For example, in case that a triggering signal for switching the state from the slide-in state to the slide-out state or from the slide-out state to the slide-in state is detected, a processor (e.g., the processor 120 in FIG. 1) of the electronic device 200 may operate the drive motor (e.g., the drive motor 260 in FIG. 4A) disposed in the electronic device 200. In the embodiment, the triggering signal may include a signal according to selection (e.g., touch) on an object displayed on the flexible display 230 or a signal according to manipulation (e.g., pressing) on a physical button (e.g., a key button) included in the electronic device 200.

According to various embodiments, the electronic device 200 has a structure in which the second housing 220 slides inward and/or slides outward relative to the first housing 210 in the longitudinal direction (e.g., vertical direction) (e.g., the ± y-axis direction) of the electronic device 200. However, the present disclosure is not limited thereto. For example, the electronic device 200 may also have a structure in which the second housing 220 slides inward and/or slides outward relative to the first housing 210 in the width direction (e.g., the horizontal direction) (e.g., the ± x-axis direction) perpendicular to the longitudinal direction of the electronic device 200. In any embodiment, the electronic device 200 may be formed such that a length of the first side surface 2111 of the first housing 210 is longer than a length of the second side surface 2112. In this case, a length of the fourth side surface 2211 of the second housing 220 may be longer than a length of the fifth side surface 2212 correspondingly.

According to various embodiments, the electronic device 200 may include an antenna A (e.g., a first antenna) disposed through at least a part of the second lateral member 221 of the second housing 220. In the embodiment, the electronic device 200 may include at least one unit conductive portion 310 or 311 formed by means of at least one segmenting portion 321, 322, or 323. In the embodiment, the electronic device 200 may include a first segmenting portion 321 disposed on the fifth side surface 2212 of the second lateral member 221, and a first conductive portion 310 disposed through a second segmenting portion 322 disposed on the fourth side surface 2211. In the embodiment, the first conductive portion 310 may be electrically connected to a wireless communication circuit (e.g., the wireless communication module 192 in FIG. 1) of the electronic device 200 and used as at least one antenna A that operates in at least one designated frequency band (e.g., a legacy band or an NR band). For example, at least one designated frequency band may include a frequency band within a range of about 600 MHz to 1000 MHz. In any embodiment, a second conductive portion 311, which is disposed by means of a third segmenting portion 323 and the second segmenting portion 322 disposed on the sixth side surface, may be used as the antenna. In the embodiment, the electronic device 200 may include another antenna A1 (e.g., a second antenna) that operates by means of a third conductive portion 312 disposed by means of a fourth segmenting portion 324 and a fifth segmenting portion 325 disposed on the first side surface 2111 of the first housing 210 and spaced apart from each other.

FIG. 4A is an exploded perspective view of the electronic device according to various embodiments of the present disclosure. FIG. 4B is a perspective view of a support bracket on which a battery according to various embodiments of the present disclosure is seated.

To describe the electronic device 200 in FIG. 4A, the constituent elements, which are substantially the same as the constituent elements of the electronic device 200 in FIGS. 2A to 3B, will be designated by the same reference numerals, and a detailed description thereof will be omitted.

With reference to FIGS. 4A and 4B, the electronic device 200 may include the first housing 210 including the first space 2101, the second housing 220 slidably coupled to the first housing 210 and including the second space 2201, the support member 240 (e.g., a bendable member or a multi-bar assembly) fixed to at least a part of the second housing 220 and at least partially bendably accommodated in the first space 2101 by the slide-in operation, the flexible display 230 disposed to be supported by at least a part of the support member 240 and the second housing 220, and a drive part (e.g., a drive module or a drive mechanism) configured to operate the second housing 220 in a slide-in direction (e.g., the −y-axis direction) and/or a slide-out direction (e.g., the y-axis direction) from the first housing 210. In the embodiment, the first housing 210 may include the first lateral member 211, and the first rear surface cover 213 (e.g., a first rear bracket) coupled to at least a part of the first lateral member 211 (e.g., at least a part of the first extension member 212). In the embodiment, the first space 2101 may be formed by coupling the first lateral member 211 and the first rear surface cover 213.

According to various embodiments, the second housing 220 may include the second lateral member 221, the second rear surface cover 223 (e.g., a second rear bracket) coupled to at least a part of the second lateral member 221 (e.g., at least a part of the second extension member 222), and the window cover 224 coupled to the second rear surface cover 223. In the embodiment, the second space 2201 may be formed by coupling the second lateral member 221 and the second rear surface cover 223.

According to various embodiments, the drive part (e.g., the drive module) may include the drive motor 260 disposed in the second space 2201 and including the pinion gear (e.g., the pinion gear 261 in FIG. 5A), and the rack gear 227 fixed to a support bracket 225, extending from the first space 2101 to the second space 2201, and disposed to gear-coupled to the pinion gear 261. In the embodiment, the electronic device 200 may further include a speed reduction module (e.g., a reduction gear assembly) coupled to the drive motor 260 to reduce a rotational speed and structurally coupled to the drive motor to increase driving power. In the embodiment, the drive motor 260 may be disposed in the second space 2201 of the second housing 220 and supported by the second extension member 222. In the embodiment, the drive motor 260 may be disposed to be supported by a motor bracket 260a fixed to the second extension member 222. In any embodiment, the rack gear 227 may be guided in the sliding direction by the motor bracket 260a. Therefore, when the electronic device 200 is assembled, the state in which the pinion gear (e.g., the pinion gear 261 in FIG. 5A) is gear-coupled to the rack gear 227 may be maintained. The pinion gear 261, which receives driving power of the drive motor 260, may move along the rack gear 227, such that the second housing 220 may move in the slide-in direction or the slide-out direction relative to the first housing 210.

According to various embodiments, the electronic device 200 may include the support bracket 225 fixed to the first space 2101 of the first housing 210. In the embodiment, the electronic device 200 may include a pair of guide rails 226 (e.g., linear motion (LM) guides) fixed to two opposite surfaces of the support bracket 225 to guide two opposite ends of the support member 240 in the sliding direction and guide the second housing 220 in the sliding direction. In the embodiment, the support bracket 225 and the pair of guide rails 226 may be fixed to the first housing 210 by means of a fastening member such as, for example, a screw, a bolt and nut, a clip, etc. In the embodiment, the support bracket may include a battery seating part 2251 configured to accommodate a battery B, and a support part 2252 formed at a lower side of the battery seating part 2251 and configured to support a rear surface of the support member 240 that is bent during the sliding operation of the second housing 220. In the embodiment, an outer surface of the support part 2252 may be formed in a curved shape to smoothly guide the support member 240. In the embodiment, the support bracket 225 and guide rails 226 may be fixed in an internal space 2101 of the first housing 210 by a fastening member such as, for example, a screw, a bolt and nut, a clip, etc. In any embodiment, the electronic device 200 may further include a battery cover 2253 coupled to the support bracket 225 to cover the mounted battery B. In the embodiment, the rack gear 227 may be fixed to the outer surface of the support bracket 225 by a fastening member (e.g., a screw, a bolt and nut, a clip, etc.) and extend in the direction of the second space 2201. In the embodiment, the rack gear 227 may be disposed at a center (e.g., a vertically symmetric center) of the support bracket 225 so as to traverse the center of the electronic device 200 in the sliding direction of the second housing 220. The center arrangement may reduce the consumption of electric current by reducing an increase in driving resistance force caused by eccentricity during the sliding operation.

According to various embodiments, the electronic device 200 may include at least one electrical component disposed in the second space 2201. In the embodiment, at least one electrical component may include a first substrate 251 (e.g., a substrate assembly or a main substrate) (e.g., layered substrates), and the second camera module 216 disposed around the first substrate 251. In any embodiment, at least one electrical component may be disposed in the first space 2101 of the first housing 210.

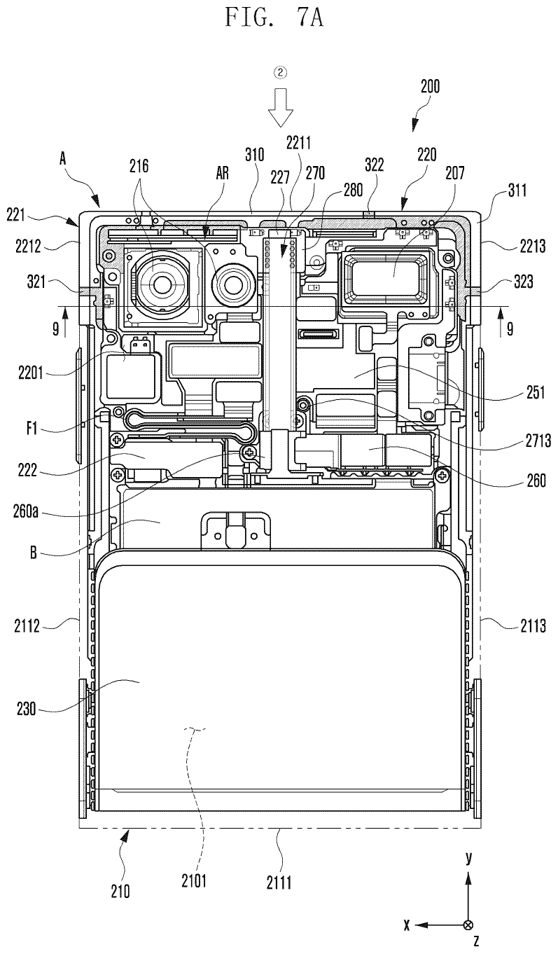

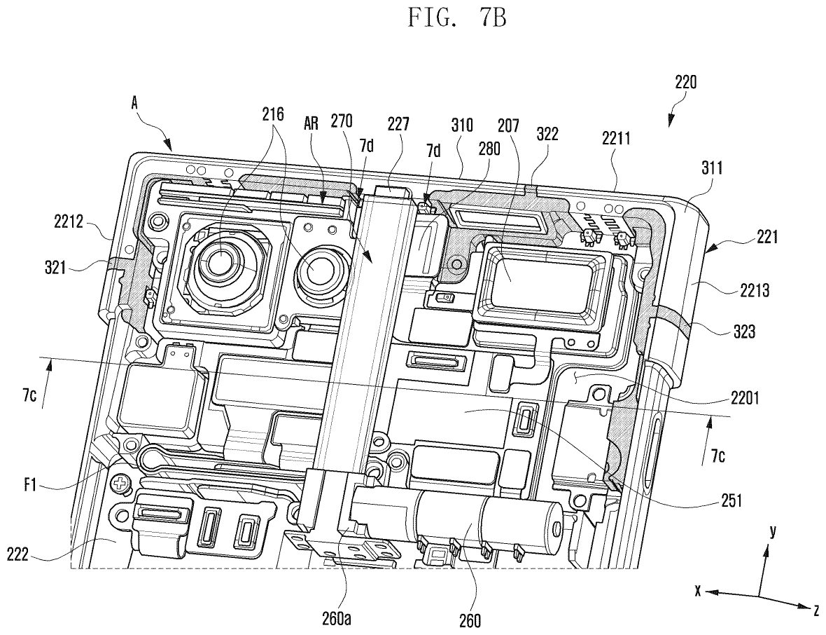

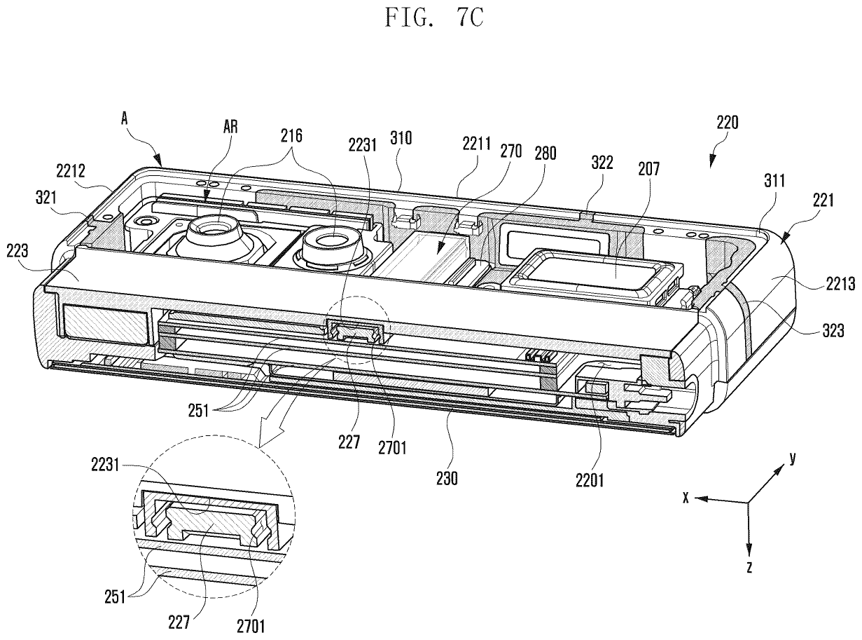

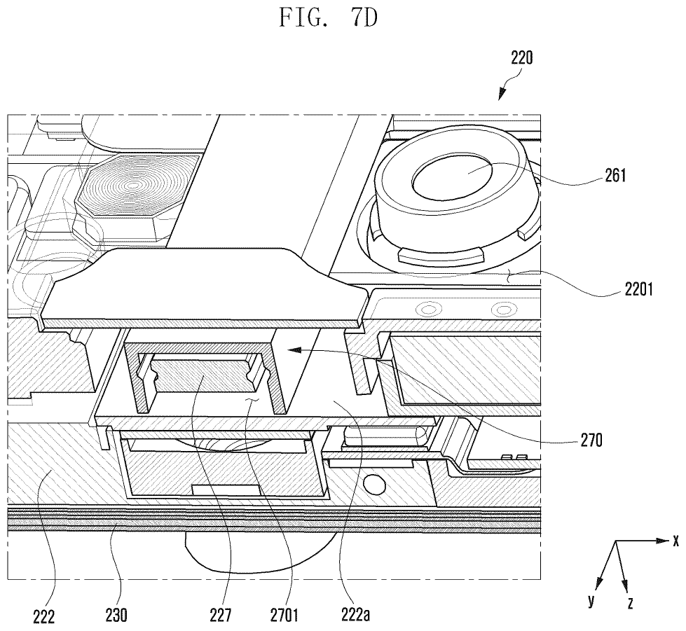

According to various embodiments, the electronic device 200 may include a second substrate 252 (e.g., a sub-substrate) and an antenna member 253 disposed between the first extension member 212 and the first rear surface cover 213 in the first housing 210. In the embodiment, the second substrate 252 and the antenna member 253 may be disposed on at least a part of the first extension member 212. In the embodiment, the second substrate 252 and the antenna member 253 may be electrically connected to the first substrate 251 through at least one electrical connection member (e.g., a flexible printed circuit board (FPCB) or a flexible RF cable (FRC)). In the embodiment, the antenna member 253 may include a multi-function coil or multi-function core (MFC) antenna for performing a wireless charging function, a near-field communication (NFC) function, and/or an electronic payment function. In any embodiment, the second substrate 252 and/or the antenna member 253 may be electrically connected to the first substrate 251 by means of a flexible substrate (e.g., a flexible substrate F1 in FIG. 7A) (e.g., a flexible printed circuit board (FPCB)) extending from the first space to the second space and configured to be elastically deformable.

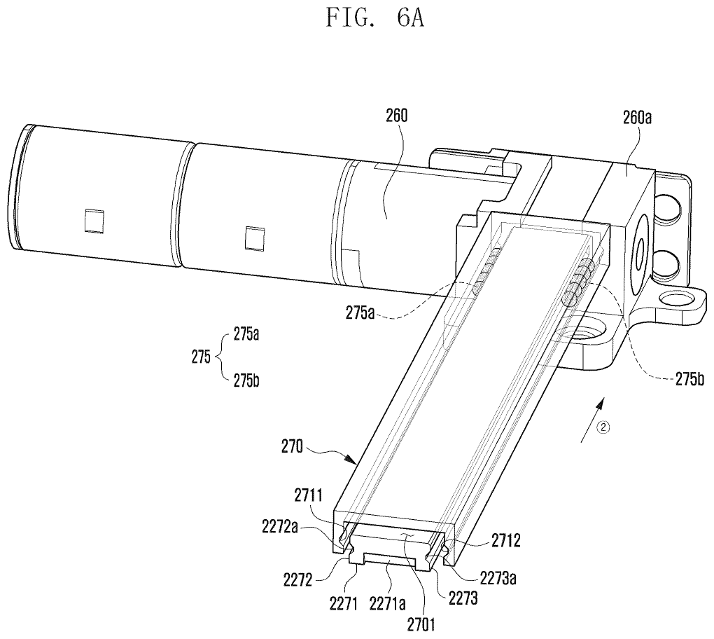

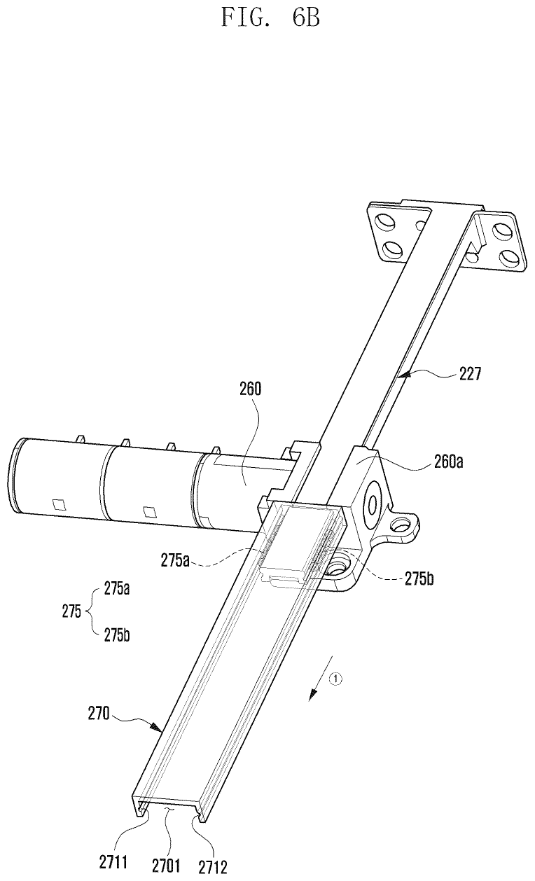

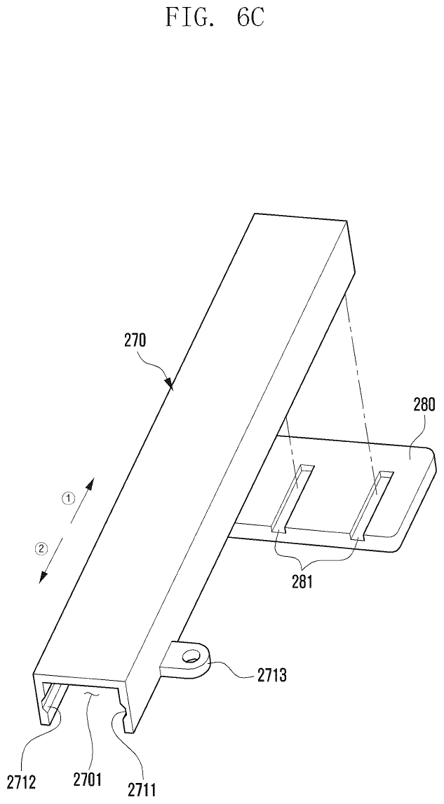

According to various embodiments, the electronic device 200 may include a guide structure 270 (e.g., a guide structure, a guide member, or a guide bracket) disposed in the second space 2201 and having an accommodation space (e.g., an accommodation space 2701 in FIG. 6A) for accommodating at least a part of the rack gear 227 that moves to the second space 2201 in the slide-in state. In the embodiment, the guide structure 270 may be disposed in the accommodation space 2701 having a length at least corresponding to a movement distance according to the sliding operation of the second housing 220 and configured to accommodate the rack gear 227. The accommodation space 2701 may improve the operational stability by reducing the introduction of external foreign substances into the rack gear 227. In the embodiment, the rack gear 227 may be installed to be supported by at least one bearing member (e.g., a bearing member 275 in FIG. 6A) disposed between the rack gear 227 and the guide structure 270 in the accommodation space 2701. In the embodiment, the guide and/or support structure of the rack gear using at least one bearing member 275 may provide an additional support structure according to the sliding operation of the electronic device 200. The at least one bearing member 275 may be configured to provide a supporting force (e.g., the first supporting force) in a direction (e.g., the first direction) which may provide a stable sliding operation even in the event of an external impact such as a fall and assist in reducing a driving resistance force of the drive motor by reducing a frictional force.

FIG. 5A is a cross-sectional view of the electronic device according to various embodiments of the present disclosure when viewed along line 5a-5a in FIG. 2A. FIG. 5B is a cross-sectional view of the electronic device according to various embodiments of the present disclosure when viewed along line 5b-5b in FIG. 3A.

To describe the electronic device 200 in FIGS. 5A and 5B, the constituent elements, which are substantially the same as the constituent elements of the electronic device 200 in FIG. 4A, will be designated by the same reference numerals, and a detailed description thereof will be omitted.

With reference to FIGS. 5A and 5B, the electronic device 200 may include the first housing 210 having the first space 2101, the second housing 220 having the second space 2201, the support member 240 connected to the second housing 220 and configured to be at least partially accommodated in the first space 2101 in the slide-in state, the flexible display 230 disposed to be supported by at least a part of the support member 240 and at least a part of the second housing 220, the rack gear 227 fixed to the first space 2101 and extending to the second space 2201, and the drive motor 260 disposed in the second space 2201 and including the pinion gear 261 gear-coupled to the rack gear 227. In the embodiment, the drive motor 260 may automatically move the second housing 220 in the slide-out direction (direction \textcircled{1}) or the slide-in direction (direction \textcircled{2}) relative to the first housing 210 by means of gear-coupling between the pinion gear 261 and the rack gear 227. In the embodiment, the electronic device 200 may include the first rear surface cover 213 coupled to the first extension member 212 extending from the first lateral member 211 of the first housing 210. In the embodiment, the electronic device 200 may include the second rear surface cover 223 coupled to the second extension member 222 extending from the second lateral member 221.

According to various embodiments, a part of the second housing 220 may be accommodated in the first space 2101 of the first housing 210 in the slide-in state (the state in FIG. 5A) of the electronic device 200. In the embodiment, at least a part of the flexible display 230 is accommodated by being bent in the first space 2101 together with the support member 240, such that at least a part of the flexible display 230 may be disposed to be invisible or hidden from the outside. In this case, the first display area of the flexible display 230 (e.g., the display area corresponding to the first part 230a in FIG. 3A) may be exposed to the outside.

According to various embodiments, at least a part of the second housing 220 may be switched, by the operation of the drive motor 260, to the slide-out state in which at least a part of the second housing 220 at least partially moves from the first housing 210 to the outside in the first direction (direction \textcircled{1}). In the embodiment, the flexible display 230 moves together with the support member 240 while being supported by the support bracket 225 in the slide-out state (the state in FIG. 5B) of the electronic device 200, such that a portion of the flexible display 230, which is slid inward in the first space 2101, may be exposed to be at least partially visible from the outside. In this case, the flexible display 230 may be configured such that the second display area (e.g., the display area including the first part 230a and the second part 230b in FIG. 3A), which is larger than the first display area, may be exposed to the outside.

According to various embodiments, the electronic device 200 may include the guide structure 270 disposed in the second space 2201 and having the accommodation space (e.g., the accommodation space 2701 in FIG. 6A) for accommodating at least a part of the rack gear 227 that moves to the second space 2201 in the slide-in state. In the embodiment, in the second space 2201, the guide structure 270 may be disposed to be in contact with an inner surface 221a of the second lateral member 221 (e.g., an inner surface of the fourth side surface 2211 in FIG. 1A) or a portion disposed in the vicinity of the inner surface 221a. In the embodiment, the guide structure 270 may be made of a metallic material and at least partially fixed to the second extension member 222 in the second space 2201 by a fastening member such as, for example, a screw, bolt and nut, clip, etc. In any embodiment, at least a part of the guide structure 222 may be disposed to be supported by at least a part of an electric structure (e.g., the first substrate (e.g., the first substrate 251 in FIG. 4A)) disposed in the second space 2201. In any embodiment, even in the slide-out state, at least a part of the rack gear 227 may be positioned in the accommodation space (e.g., the accommodation space 2701 in FIG. 6A) of the guide structure 270. In any embodiment, in the slide-out state, the rack gear 227 may completely depart from the accommodation space 2701 of the guide structure 270.

According to various embodiments, the rack gear 227 gradually enters the accommodation space (e.g., the accommodation space 2701 in FIG. 6A) of the guide structure 270 while the electronic device 200 switches from the slide-out state to the slide-in state. In the completely slide-in state, an end of the rack gear 227 may be positioned in the vicinity of the inner surface 221a of the second lateral member 221. In this case, the rack gear 227 made of a metallic material is positioned in the vicinity of the conductive portion (e.g., the first conductive portion 310 in FIG. 1A) disposed as a part of the second lateral member 221 and used as the antenna (e.g., the antenna A in FIG. 1A), which may degrade the radiation performance of the antenna A. Therefore, according to the exemplary embodiment of the present disclosure, the guide structure 270 may be made of a metallic material and electrically connected to the ground of the electronic device 200 (e.g., the ground of the first substrate). In addition, the rack gear 227 may be electrically connected to the guide structure 270 through the bearing member (e.g., the bearing member 275 in FIG. 6A), and as a result, the rack gear 227 may also be electrically connected to the ground of the rack gear 227. The ground connection structure of the rack gear 227 implemented by the guide structure 270 may assist in reducing the degradation of the radiation performance of the antenna A.

In any embodiment, the rack gear 227 may be disposed in the second housing 220, and the guide structure 270, which is configured to accommodate the drive motor 260 including the pinion gear 261 and at least a part of the rack gear 227, may be disposed in the first housing 210.

FIG. 6A is a view illustrating arrangement positions of the rack gear and the guide structure in the slide-in state according to various embodiments of the present disclosure. FIG. 6B is a view illustrating arrangement positions of the rack gear and the guide structure in the slide-out state according to various embodiments of the present disclosure.

With reference to FIGS. 6A and 6B, the electronic device (e.g., the electronic device 200 in FIG. 4A) may include the rack gear 227 fixed to at least a part (e.g., the support bracket 225 in FIG. 4A) of the first housing (e.g., the first housing 210 in FIG. 4A) and extending to the second housing (e.g., the second housing 220 in FIG. 4A), and the drive motor 260 disposed in the second housing 220 and including the pinion gear (e.g., the pinion gear 261 in FIG. 5A) gear-coupled to the rack gear 227.

According to various embodiments, the electronic device 200 may include the guide structure 270 disposed in the second housing 220 and having the accommodation space 2701 for accommodating at least a part of the rack gear 227 in the slide-in state. In the embodiment, the rack gear 227 may include a gear surface 2271 having a rack gear portion 2271a, and a first side surface 2272 and a second side surface 2273 extending from the gear surface 2271 in directions opposite to each other.

According to various embodiments, the electronic device 200 may include at least one bearing member 275 (e.g., a first bearing member) (e.g., a first supporting member) disposed between the first side surface 2272 and the guide structure 270 and/or between the second side surface 2273 and the guide structure 270 in the accommodation space 2701. In the embodiment, at least one bearing member 275 may include a bearing member 275a disposed between a first guide groove 2272a formed in the first side surface 2272 and a second guide groove 2711 formed in a corresponding inner surface of the guide structure 270. In the embodiment, at least one bearing member 275 may include a bearing member 275b disposed between a third guide groove 2273a formed in the second side surface 2273 and a fourth guide groove 2712 formed in a corresponding inner surface of the guide structure 270. In the embodiment, the rack gear 227, the bearing member 275, and the guide structure 270 may be made of a metallic material. In the embodiment, the rack gear 227 may be electrically connected to the guide structure 270 through the bearing member 275.

According to various embodiments, the drive motor 260 may be supported by the motor bracket 260a fixed to the second housing 220. In the embodiment, the rack gear 227 may be slidably coupled to the motor bracket 260a and gear-coupled to the pinion gear (e.g., the pinion gear 261 in FIG. 5A). In the embodiment, the guide structure 270 may be disposed to be in contact with the motor bracket 260a. Therefore, it is possible to reduce the introduction of foreign substances between the guide structure 270 and the motor bracket 260a and reduce a situation in which a lubricant such as grease applied to the gear-coupling portion between the rack gear 227 and the pinion gear 261 leaks to the outside and affects surrounding electric structures.

FIG. 6C is a perspective view of the guide structure according to various embodiments of the present disclosure.

With reference to FIG. 6C, the guide structure 270 may be fixed to the second housing 220 by at least one fixing piece 2713 at least partially extending to the outside. In the embodiment, the guide structure 270 may be fixed as a fastening member, such as, for example, a screw, a bolt and nut, a clip, etc. is fastened to an internal structure (e.g., the second extension member 222 and/or the first substrate 251) through a through-hole formed in the fixing piece 2713. In the embodiment, the electronic device 200 may further include an alignment member 280 configured to easily guide the assembling of the guide structure 270 disposed in the second housing 220 and easily align the rack gear 227. In the embodiment, the alignment member 280 may include at least one alignment guide groove 281 disposed in the internal space 2201 of the second housing 220 and configured to accommodate a part of the guide structure 270. In any embodiment, the alignment member 280 may be excluded. In any embodiment, the guide structure 270 may also be fixed to an exact position on the second space 2201 of the second housing 220 by bonding, taping, or welding without the fixing piece 2713.

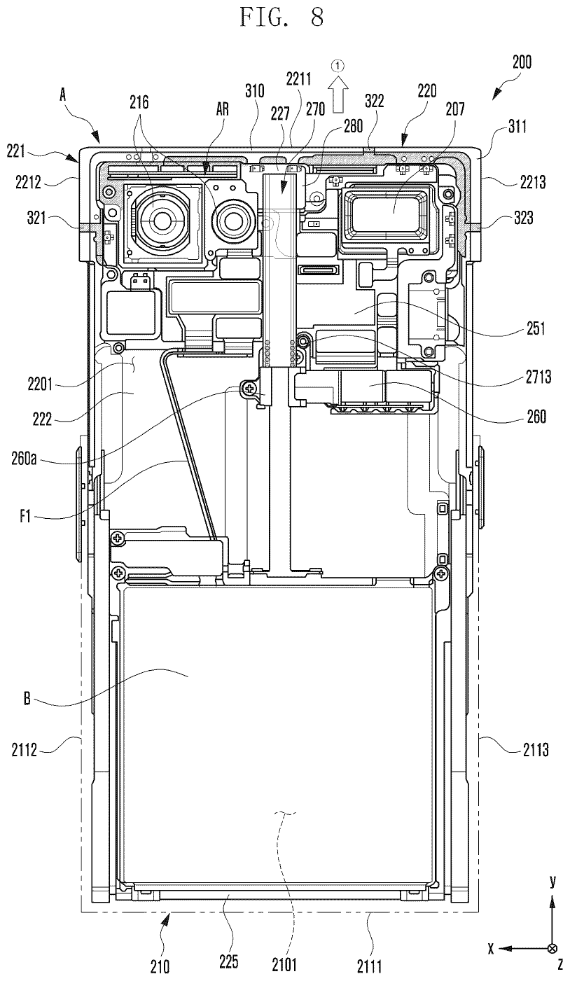

FIG. 7A is a configuration view illustrating the rear surface of the electronic device in the slide-in state according to various embodiments of the present disclosure. FIG. 7B is a perspective view illustrating the rear surface of the second housing in the slide-in state according to various embodiments of the present disclosure. FIG. 7C is a cut-away perspective view of the second housing according to various embodiments of the present disclosure when viewed along line 7c-7c in FIG. 7B. FIG. 7D is a partially cut-away perspective view of the second housing according to various embodiments of the present disclosure when viewed along line 7d-7d in FIG. 7B. FIG. 8 is a configuration view illustrating the rear surface of the electronic device in the slide-out state according to various embodiments of the present disclosure.

To describe the electronic device 200 in FIGS. 7A to 8, the constituent elements, which are substantially the same as the constituent elements of the electronic device 200 in FIGS. 4A to 6C, will be designated by the same reference numerals, and a detailed description thereof will be omitted.

With reference to FIGS. 7A to 8, the electronic device 200 may include the first housing 210, and the second housing 220 slidably coupled to the first housing. In the embodiment, the electronic device 200 may include at least one electrical component disposed in the second space 2201 of the second housing 220. In the embodiment, at least one electrical component may include the first substrate 251 disposed in the second space 2201. In the embodiment, the first substrate 251 may include a substrate assembly disposed such that a plurality of substrates is stacked by means of an interposer. In the embodiment, at least one electrical component may include at least one of the camera module 216, the speaker 207, and an array antenna AR disposed around the first substrate 251. In the embodiment, the array antenna AR may be disposed to form beam patterns in a designated frequency band (e.g., a frequency band within a range of about 3 GHz to 100 GHz) in a designated direction (e.g., a direction toward the fourth side surface 2211). In the embodiment, the first substrate 251 of the first housing 210 and the second substrate (e.g., the second substrate 252 in FIG. 4) of the second housing 220 may be electrically connected by the flexible substrate F1 that is elastically deformable.

According to various embodiments, the electronic device 200 may include the guide structure 270 disposed in the second space 2201 of the second housing 220 and having the accommodation space 2701 for accommodating at least a part of the rack gear 227 that moves to the second space 2201 in the slide-in state. In the embodiment, the guide structure 270 may be made of a metallic material and at least partially fixed to the second extension member 222 in the second space 2201 by a fastening member such as, for example, a screw, a bolt and nut, a clip, etc. In the embodiment, the guide structure 270 may be formed in a partially opened shape. When the guide structure 270 is installed in the second space 2201, the accommodation space 2701 for the rack gear 227 may be formed together with the internal structure (e.g., the second extension member 222 and/or the first substrate 251).

According to various embodiments, the guide structure 270 may be disposed between the second extension member 222 and the second rear surface cover 223 in the second space 2201 of the second housing 220. In the embodiment, the guide structure 270 may be fixed to the second extension member 222 by means of the fixing piece 2713. In the embodiment, the guide structure 270 may be disposed to be aligned with the rack gear 227 by means of the alignment member 280. In the embodiment, the guide structure 270 may be disposed to be in contact with the rear surface cover 223. In the embodiment, the guide structure 270 may be supported by being seated in a recess 2231 formed to be lower than an outer surface of the rear surface cover 223. In the embodiment, the recess seating structure of the guide structure 270 may assist in reducing an inadvertent movement of the guide structure 270 during the sliding operation and reducing a thickness of the electronic device 200.

With reference to FIG. 7D, the guide structure 270 made of a metallic material may be electrically connected to the rack gear 227 through the bearing member 275. For example, in the slide-in state, the antenna A, which operates by means of the conductive portion 310 disposed around the rack gear 227, may deteriorate in radiation performance because of the proximity of the rack gear 227. Therefore, the guide structure 270 needs to be electrically connected to the ground of the electronic device 200. In the embodiment, the guide structure 270 may be disposed to be spaced apart from the second extension member 222 electrically connected to the ground so that the surrounding structures may be efficiently disposed. In this case, the guide structure 270 may be electrically connected to the ground through a conductive bracket 222a disposed between the guide structure 270 and the second extension member 222 while being in contact with the guide structure 270 and the second extension member 222. In any embodiment, at least a part of the guide structure 270 may be disposed to be physically in direct contact with the ground of the first substrate 251.

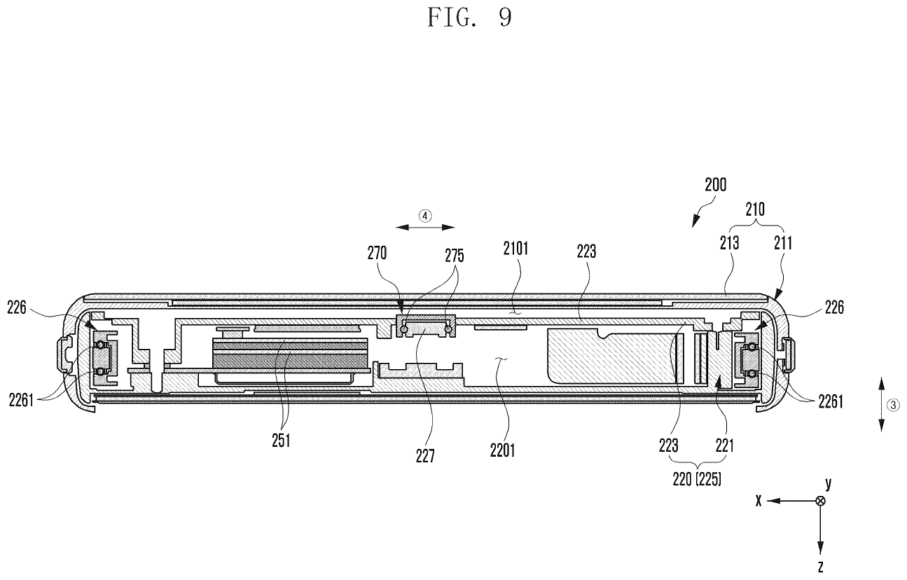

FIG. 9 is a cross-sectional view of the electronic device according to various embodiments of the present disclosure when viewed along line 9-9 in FIG. 7A.

With reference to FIG. 9, the electronic device 200 may include the first housing 210 having the first space 2101, the second housing 220 having the second space 2201, the flexible display 230 connected to the second housing 220 and configured to at least partially accommodate the first space 2101 in the slide-in state, the rack gear 227 fixed to the first housing 210 (e.g., the support bracket 225) and extending to the second space 2201, and the guide structure 270 disposed in the second space 2201 and including the accommodation space 2701 configured to accommodate the rack gear 227.

According to various embodiments, the electronic device 200 may include the pair of guide rails 226 disposed between the first housing 210 and the second housing 220. In the embodiment, the pair of guide rails 226 may be disposed on the left and right side surfaces of the electronic device 200 and slidably guide the first housing 210 and the second housing 220 relative to each other by means of at least one bearing member 2261 (e.g., the second bearing member) (e.g., a second supporting member). In the embodiment, at least one bearing member 2261 may be coupled to the guide rails 226 and configured to provide a supporting force (e.g., a second supporting force) in a second direction (e.g., a direction opposite to the first direction provided by the bearing member 275) to support the first housing 210 and the second housing 220 in a third direction (e.g., direction \textcircled{3}) (e.g., the ± z-axis direction) perpendicular to the flexible display 230. In the embodiment, at least one bearing member 275 (e.g., the first bearing member) disposed between the rack gear 227 and the guide structure 270 may be disposed to support the rack gear 227 and the guide structure 270 in a direction (e.g., direction \textcircled{4}) (e.g., the ± x-axis direction) parallel to the flexible display 230. For example, the electronic device 200 may have an additional support structure, which provides a supporting force (e.g., the first supporting force) in a direction (e.g., the first direction) different from the second direction of the second support force provided by the at least one bearing member 2261 disposed on the guide rail 226, by means of the at least one bearing member 275 disposed between the rack gear 227 and the guide structure 270. Accordingly, the rack gear 227 and the at least one bearing member 2261 may assist in implementing the stable sliding operation of the electronic device 200.

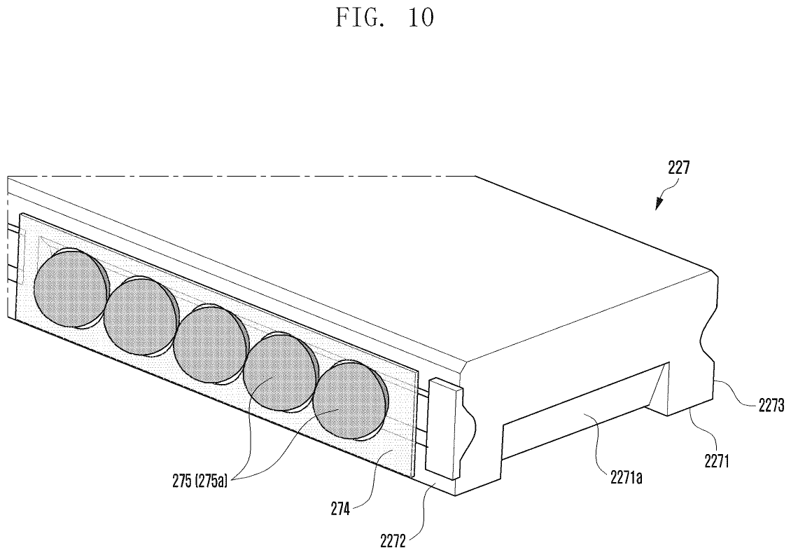

FIG. 10 is a partial perspective view of the rack gear according to various embodiments of the present disclosure.

With reference to FIG. 10, the rack gear 227 may include the gear surface 2271 including the rack gear portion 2271a gear-coupled to the pinion gear (e.g., the pinion gear 261 in FIG. 5A), the first side surface 2272 extending to one side of the gear surface 2271, and the second side surface 2273 extending to the other side of the gear surface 2271. In the embodiment, the rack gear 271 may include at least one bearing member 275 disposed on the first side surface 2272 and/or the second side surface 2273 and being rotatably in contact with the guide structure (e.g., the guide structure 270 in FIG. 5A). In the embodiment, because at least one bearing member 275 arbitrarily moves together with the relative movements of the rack gear 227 and the guide structure 270, at least one bearing member 275 may depart from the guide structure 270. It may also be difficult for at least one bearing member 275 to be used as a current application means with the rack gear 227 at the end of the guide structure 270. Therefore, according to the exemplary embodiment of the present disclosure, the rack gear 227 may restrict, by means of a bearing fixing member 274 disposed at an end thereof, a position of at least one bearing member 275 so that at least one bearing member 275 does not arbitrarily move. Implementing the bearing fixing member 274 may allow at least one bearing member 275 to support the rack gear 227 and the guide structure 270 so that the rack gear 227 and the guide structure 270 are stably rotatable at a designated position (e.g., an end of the rack gear) on the rack gear 227.

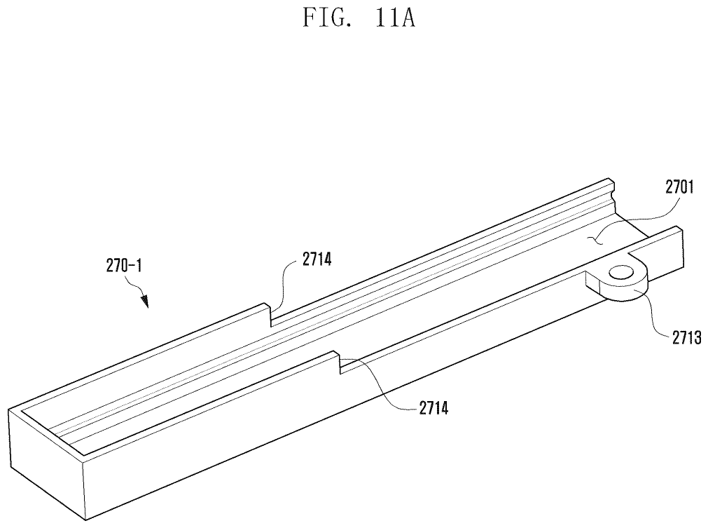

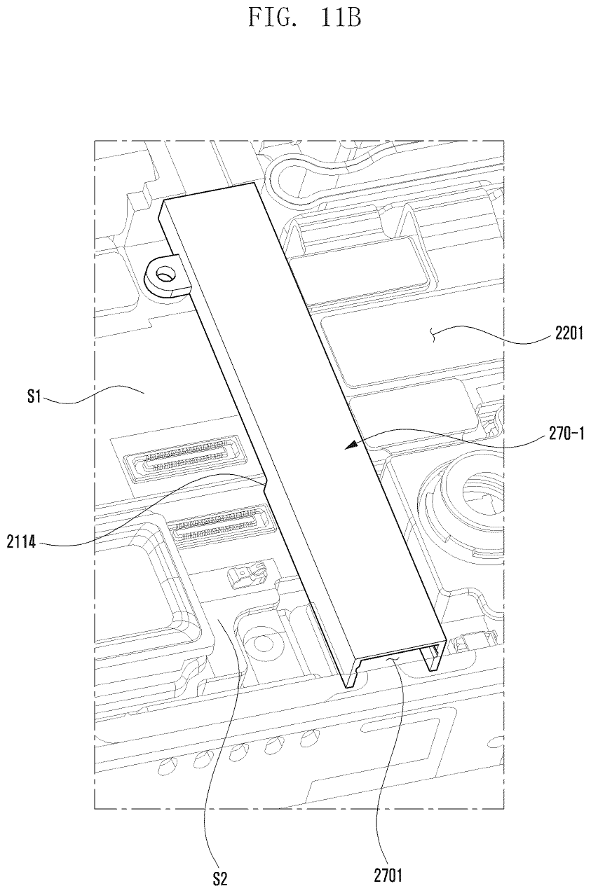

FIG. 11A is a perspective view of the guide structure according to various embodiments of the present disclosure. FIG. 11B is a view illustrating a state in which the guide structure in FIG. 11A according to various embodiments of the present disclosure is applied to the electronic device.

With reference to FIGS. 11A and 11B, a shape of a guide structure 270-1 (e.g., the guide structure 270 in FIG. 7A) may be determined in consideration of the arrangement of the structures (e.g., the first substrate, the electric elements, the bracket, or the extension member) disposed in the second space 2201 of the second housing (e.g., the second housing 220 in FIG. 7A). For example, the guide structure 270-1 may include at least one stepped portion 2714. In the embodiment, when the guide structure 270-1 including at least one stepped portion 2714 is disposed in the second space 2201 of the second housing 220, the guide structure 270 appropriately corresponds to the stepped areas of a first structure S1 (e.g., the first substrate 251) and a second structure S2 (e.g., a second extension member or electric elements), such that the guide structure 270 may provide the accommodation space 2701 for the rack gear (e.g., the rack gear 227 in FIG. 7A). In the embodiment, it is apparent that the guide structure 270 can be formed in various shapes, which may correspond to the arrangement of various structures disposed in the second space 2201, in addition to the configuration of at least one stepped portion, in order to provide the space for the rack gear 227.

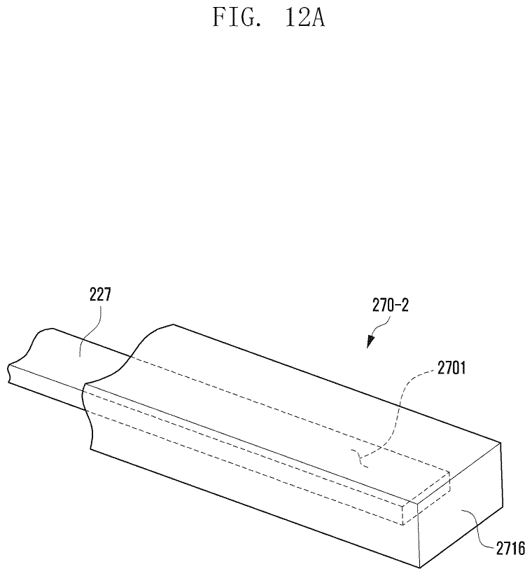

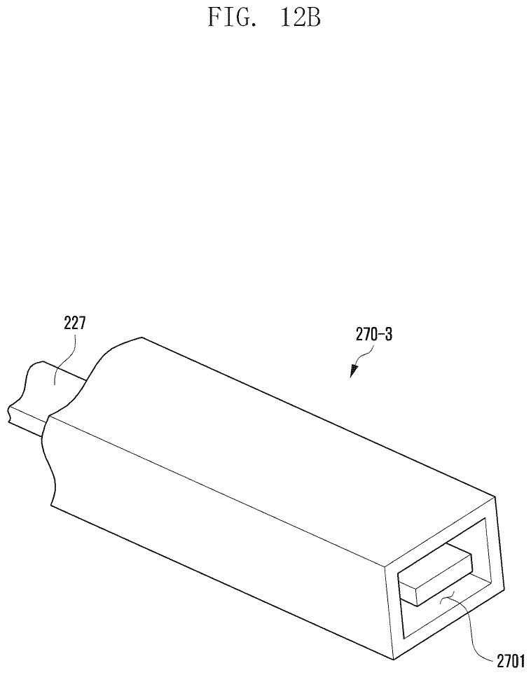

FIGS. 12A and 12B are partial perspective views of the guide structure according to various embodiments of the present disclosure.

With reference to FIG. 12A, a guide structure 270-2 (e.g., the guide structure 270 in FIG. 7A) may be formed to have a closed end 2716. In the embodiment, in the slide-in state, the closed end 2716 of the guide structure 270 may prevent the degradation of radiation performance of the antenna (e.g., the antenna A in FIG. 7A) caused by the rack gear 227 protruding from the guide structure 270.

With reference to FIG. 12B, a guide structure 270-3 (e.g., the guide structure 270 in FIG. 7A) may be formed to have the accommodation space 2701 entirely closed without being partially opened. The entire accommodation space of the guide structure 270-3 may assist in providing the stable support structure of the rack gear 227.

According to various embodiments, the electronic device may include a first housing (e.g., the first housing 210 in FIG. 7A), a second housing (e.g., the second housing 220 in FIG. 7A) slidably coupled to the first housing, a drive part providing a driving force for sliding the second housing and including a pinion gear (e.g., the pinion gear 261 in FIG. 5A), and a drive motor (e.g., the drive motor 260 in FIG. 7A) configured to rotate the pinion gear, a rack gear (e.g., the rack gear 227 in FIG. 7A) gear-coupled to the pinion gear and configured to reciprocate in a predetermined section in accordance with a rotation of the pinion gear, and a guide structure (e.g., the guide structure 270 in FIG. 7A) including an accommodation space (e.g., the accommodation space 2701 in FIG. 7C) configured to accommodate at least a part of the rack gear, and configured to guide the moving rack gear.

According to various embodiments, the accommodation space may surround at least a part of the rack gear.

According to various embodiments, the guide structure may be fixed to the second housing by means of at least one fixing structure (e.g., the fixing piece 2713 in FIG. 6C).

According to various embodiments, the electronic device may include a first bearing member (e.g., the bearing member 275 in FIG. 6A) disposed between the rack gear and the guide structure in the accommodation space.

According to various embodiments, the rack gear may include a gear surface (e.g., the gear surface 2271 in FIG. 6A) including a rack gear portion, and a first side surface (e.g., the first side surface 2272 in FIG. 6A) and a second side surface (e.g., the second side surface 2273 in FIG. 6A) extending from the gear surface in directions opposite to each other, and the first bearing member may be disposed between the first side surface and the guide structure and/or between the second side surface and the guide structure.

According to various embodiments, the guide structure may include guide grooves (e.g., a second guide groove 2711 and a fourth guide groove 2712 in FIG. 6A) formed in a sliding direction of the rack gear between the first side surface and/or the second side surface and the guide structure, and at least a part of the first bearing member may be disposed to be accommodated in the guide groove.

According to various embodiments, the first bearing member may be rotatably supported by the rack gear by means of a bearing fixing member (e.g., the bearing fixing member 274 in FIG. 10).

According to various embodiments, the guide structure may be made of a metallic material and electrically connected to a ground of the electronic device.

According to various embodiments, the rack gear may be made of a metallic material and electrically connected to the guide structure through the first bearing member.

According to various embodiments, the electronic device may include a pair of guide rails (e.g., the guide rails 226 in FIG. 9) disposed to be guided relative to each other by means of a second bearing member (e.g., a second bearing member 2261 in FIG. 9) between the first housing and the second housing, and the pair of guide rails may be disposed such that the second bearing member supports the first housing and the second housing in a first direction (e.g., direction \textcircled{3} in FIG. 9).

According to various embodiments, the first bearing member may be disposed to support the rack gear and the guide structure in a second direction (e.g., direction \textcircled{4} in FIG. 9) perpendicular to the first direction.

According to various embodiments, the electronic device may include motor bracket (e.g., the motor bracket 260a in FIG. 7A) disposed in the second housing and configured to support at least one of the drive motor and the pinion gear, and the rack gear may be slidably coupled to the motor bracket.

According to various embodiments, one end of the guide structure may be disposed to be in contact with the motor bracket.

According to various embodiments, the second housing may include a lateral member (e.g., the second lateral member 221 in FIG. 7A) configured to define at least a part of an external appearance of the electronic device, an extension member (e.g., the second extension member 222 in FIG. 7A) extending to an internal space from the lateral member, and a rear surface cover (e.g., the second rear surface cover 223 in FIG. 7A) coupled to the lateral member, and the guide structure may be disposed between the extension member and the rear surface cover.

According to various embodiments, the guide structure may be fixed to at least a part of the extension member.

According to various embodiments, the guide structure may be supported by being in contact with the rear surface cover.

According to various embodiments, the rear surface cover may at least partially include a recess (e.g., the recess 2231 in FIG. 7C) configured to accommodate at least a part of the guide structure.

According to various embodiments, the guide structure may provide the accommodation space by being coupled to a structure disposed in the second housing.

According to various embodiments, the rack gear and the guide structure may be disposed to traverse a center of the electronic device in the sliding direction.

According to various embodiments, the electronic device may include a flexible display (e.g., the flexible display 230 in FIG. 7C) disposed to be at least partially supported by the second housing and having a display area that varies depending on the slide-in or slide-out operation of the second housing.

Further, the embodiments of the present disclosure disclosed in the present specification and illustrated in the drawings are provided as particular examples for easily explaining the technical contents according to the embodiment of the present disclosure and helping understand the embodiment of the present disclosure, but not intended to limit the scope of the embodiment of the present disclosure. Accordingly, the scope of the various embodiments of the present disclosure should be interpreted as including all alterations or modifications derived from the technical spirit of the various embodiments of the present disclosure in addition to the disclosed embodiments.

1. An electronic device comprising:
a first housing (210);
a second housing (220) slidably coupled to the first housing;
a drive part providing a driving force for sliding the second housing and comprising a pinion gear (261), and a drive motor (260) configured to rotate the pinion gear;
a rack gear (227) gear-coupled to the pinion gear and configured to reciprocate in a predetermined section in accordance with a rotation of the pinion gear; and
a guide structure (270) comprising an accommodation space (2701) configured to accommodate at least a part of the rack gear and configured to guide the moving rack gear.

2. The electronic device of claim 1, wherein the accommodation space surrounds at least a part of the rack gear.

3. The electronic device of claim 1, wherein the guide structure is fixed to the second housing by means of at least one fixing structure (2713).

4. The electronic device of claim 1, comprising:
a first bearing member (275) disposed between the rack gear and the guide structure in the accommodation space.

5. The electronic device of claim 4, wherein the rack gear comprises:
a gear surface (2271) comprising a rack gear portion; and
a first side surface (2272) and a second side surface (2273) extending from the gear surface in directions opposite to each other, and
wherein the first bearing member is disposed between the first side surface and the guide structure and/or between the second side surface and the guide structure.

6. The electronic device of claim 5, wherein the guide structure comprises guide grooves (2711, 2712) formed in a sliding direction of the rack gear between the first side surface and/or the second side surface and the guide structure, and
wherein at least a part of the first bearing member is disposed to be accommodated in the guide groove.

7. The electronic device of claim 4, wherein the first bearing member is rotatably supported by the rack gear by means of a bearing fixing member (274).

8. The electronic device of claim 4, wherein the guide structure is made of a metallic material and electrically connected to a ground of the electronic device.

9. The electronic device of claim 8, wherein the rack gear is made of a metallic material and electrically connected to the guide structure through the first bearing member.

10. The electronic device of claim 1, comprising:
a pair of guide rails (226) disposed to be guided relative to each other by means of a second bearing member (2261) between the first housing and the second housing,
wherein the pair of guide rails is disposed so that the second bearing member supports the first housing and the second housing in a first direction (direction \textcircled{3}).

11. The electronic device of claim 10, wherein the first bearing member is disposed to support the rack gear and the guide structure in a second direction (direction \textcircled{4}) perpendicular to the first direction.

12. The electronic device of claim 1, comprising:
a motor bracket (260a) disposed in the second housing and configured to support at least one of the drive motor and the pinion gear,
wherein the rack gear is slidably coupled to the motor bracket.

13. The electronic device of claim 12, wherein one end of the guide structure is disposed to be in contact with the motor bracket.

14. The electronic device of claim 1, wherein the second housing comprises:
a lateral member (221) configured to define at least a part of an external appearance of the electronic device;
an extension member (222) extending to an internal space from the lateral member; and
a rear surface cover (223) coupled to the lateral member, and
wherein the guide structure is disposed between the extension member and the rear surface cover.

15. The electronic device of claim 14, wherein the guide structure is fixed to at least a part of the extension member.

16. An electronic device comprising:
a first housing (210);
a second housing (220) slidably coupled to the first housing;
a pair of guide rails (226) disposed to be guided relative to each other between the first housing and the second housing;
a drive part disposed in the second housing and comprising a pinion gear (261), and a drive motor (260) configured to rotate the pinion gear;
a rack gear (227) disposed in the first housing and gear-coupled to the pinion gear, the rack gear being configured to reciprocate in a predetermined section in accordance with a rotation of the pinion gear; and
a guide structure (270) disposed in the second housing, comprising an accommodation space (2701) configured to accommodate at least a part of the rack gear, and configured to guide the rack gear while in motion,
a first supporting member (275) disposed between the rack gear (227) and the guide structure (270), the first supporting member (275) configured to provide a first supporting force in a first direction; and
a second supporting member (2261) coupled to the guide rails (226), the second supporting member (2261) configured to provide a second supporting force in a second direction opposite the first direction.

17. The electronic device of claim 16, wherein the first supporting force reduces a driving resistance force of the drive motor (260), and wherein the second supporting force supports the first housing (210) and the second housing (220).

18. The electronic device of claim 17, wherein the second supporting force supports the first housing (210) and the second housing (220) in a direction perpendicular to a flexible display (230) of the electronic device.

19. The electronic device of claim 18, wherein the first supporting member (275) is a bearing member (275) and the second supporting member (2261) is a second bearing member (2261).

20. The electronic device of claim 19, wherein the second bearing member (2261) is configured to guide the pair of guide rails (226) relative to each other.
